(19) United States
(12) Patent Application Publication
(10) Pub. No.: US 2010/0206222 A1
(43) Pub. Date: Aug. 19, 2010

(54) Mask adhesion unit and deposition apparatus using the same

(76) Inventors: Dong-Young Sung, Yongin-City (KR); Jae-Jung Kim, Yongin-City (KR)

Correspondence Address: LEE & MORSE, P.C., 3141 FAIRVIEW PARK DRIVE, SUITE 500, FALLS CHURCH, VA, 22042, US

(21) Appl. No.: 12/656,406

(22) Filed: Jan. 28, 2010

(30) Foreign Application Priority Data
Feb. 19, 2009 (KR) 10-2009-0013958

(51) Int. Cl. B05C 21/00

(52) U.S. Cl. 118/69; 118/504

(57) ABSTRACT

A mask adhesion unit for a deposition apparatus includes a magnetic assembly, a cap plate spaced apart from the magnetic assembly, and a magnetic control unit between edges of the magnetic assembly, and the cap plate. A deposition apparatus using the same is capable of adhering a substrate and a mask assembly together using the mask adhesion unit to improve deposition precision, while preventing deformation of a slit of the mask assembly.

### BACKGROUND

1. Field

Embodiments relate to a mask adhesion unit and a deposition apparatus using the same and, more particularly, to a mask adhesion unit and a deposition apparatus using the same that are capable of preventing deformation of a slit of the mask assembly.

2. Description of the Related Art

Flat panel display devices, e.g., a liquid crystal display (LCD) device and an organic light emitting diode (OLED) display device, have been used as alternative display devices of cathode ray tube (CRT) display devices because they are light and slim. The OLED display device has many advantages over the LCD display device. For example, the OLED display device has better brightness and larger viewing angle than the LCD display device, while having a super-slim structure since a backlight unit can be removed.

The OLED display device is a display device using a phenomenon in which an electron injected from a cathode into an organic thin film is re-coupled to a hole injected from an anode to form an exciton, which emits lights.

To selectively form the cathode, anode, organic thin film, etc., on a substrate formed of, e.g., glass, stainless steel or synthetic resin, a photolithography method or a deposition method is used. The deposition method uses a mask assembly having a pattern including a plurality of slits. In the photolithography method, where photoresist is applied to a certain region of the substrate and then wet-etched or dry-etched, moisture may be introduced into the photoresist during a photoresist separation process or an etching process. Therefore, when organic thin film is formed of a material which may be deteriorated by moisture, the deposition method using a mask assembly may be used.

The OLED display device includes OLEDs having R, G, and B organic emission layers to display full-color. For example, during formation of the OLED display device via a conventional deposition method, a mask assembly having a plurality of openings may be aligned on a substrate on which a deposition material, e.g., R, G, and B organic emission layers for the OLEDs, is to be formed. Then, the R, G, and B organic emission layers may be provided onto the substrate through the openings of the mask assembly to deposit a desired pattern on the substrate. As a result, the OLED including the R, G, and B organic emission layers may be formed at a certain region of the substrate.

A deposition apparatus using a conventional mask assembly may include a mask adhesion unit having a magnetic material to adhere the mask assembly and the substrate. However, the magnetic material in the conventional mask adhesion unit may exert non-uniform magnetic force on the mask assembly, thereby causing mask assembly deformation.

### SUMMARY OF THE INVENTION

Embodiments are therefore directed to a mask adhesion unit and deposition apparatus using the same, which substantially overcome one or more of the problems due to the limitations and disadvantages of the related art.

It is therefore a feature of an embodiment to provide a mask adhesion unit and a deposition apparatus using the same that are capable of minimizing disproportional application of a magnetic force to a mask assembly by a magnetic material of the mask adhesion unit to prevent deformation of a slit of the mask assembly.

At least one of the above and other features and advantages may be realized by providing a mask adhesion unit for a deposition apparatus, including a magnetic assembly, a cap plate spaced apart from the magnetic assembly, and a magnetic control unit between edges of the magnetic assembly and the cap plate.

The magnetic control unit may include a magnetic shielding material or a ferrite magnetic material.

The magnetic control unit may include a ferrite magnetic material, the magnetic control unit being a thin film sheet formed of steel.

The magnetic control unit may overlap two surfaces of the magnetic assembly.

A portion of the magnetic control unit may be between the magnetic assembly and the cap plate.

The cap plate may have a plurality of coolant passages.

The magnetic assembly may include a magnetic plate and a magnetic material applied to a surface of the magnetic plate facing the cap plate.

The magnetic control unit may overlap two surfaces of the magnetic material, the magnetic control unit covering a side surface of the magnetic material.

The magnetic material of the magnetic assembly may be a metal-based material.

At least one of the above and other features and advantages may also be realized by providing a deposition apparatus, including a chamber, a deposition source in the chamber, a mask assembly over the deposition source, and a mask adhesion unit over the mask assembly, wherein the mask adhesion unit includes a magnetic assembly, a cap plate spaced from the magnetic assembly, and a magnetic control unit between edges of the magnetic assembly and the cap plate.

The magnetic control unit may include a magnetic shielding material or a ferrite magnetic material.

The magnetic control unit may include a ferrite magnetic material, the magnetic control unit being a thin film sheet formed of steel.

The cap plate may have a plurality of coolant passages.

The magnetic assembly may include a magnetic plate and a magnetic material applied to a surface of the magnetic plate facing the cap plate.

The magnetic material of the magnetic assembly may be a metal-based material.

The mask assembly may include a mask frame having an opening and at least one pattern mask extending to be fixed to the mask frame.

The pattern mask may be a fine metal mask.

The mask frame may be formed of a metal material.

The deposition apparatus may further include a mask holder for coupling the mask assembly to the chamber.

The mask holder may have a plurality of coolant passages.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic view of a deposition apparatus in accordance with an exemplary embodiment; and

FIG. 2 illustrates an enlarged view of a mask assembly and a mask adhesion unit of FIG. 1.

### DETAILED DESCRIPTION

Korean Patent Application No. 10-2009-0013958, filed on Feb. 19, 2009, in the Korean Intellectual Property Office, and entitled: “Mask Adhesion Unit and Deposition Apparatus Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

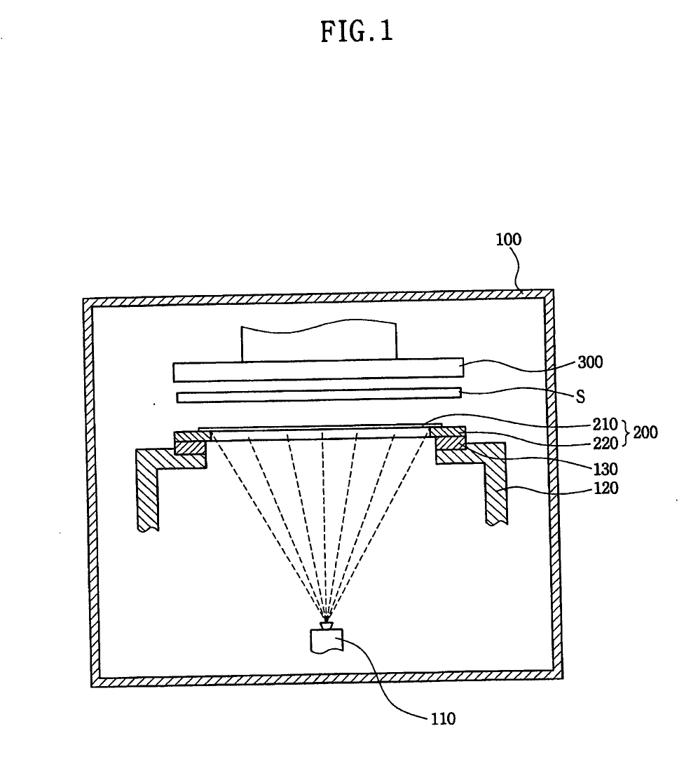

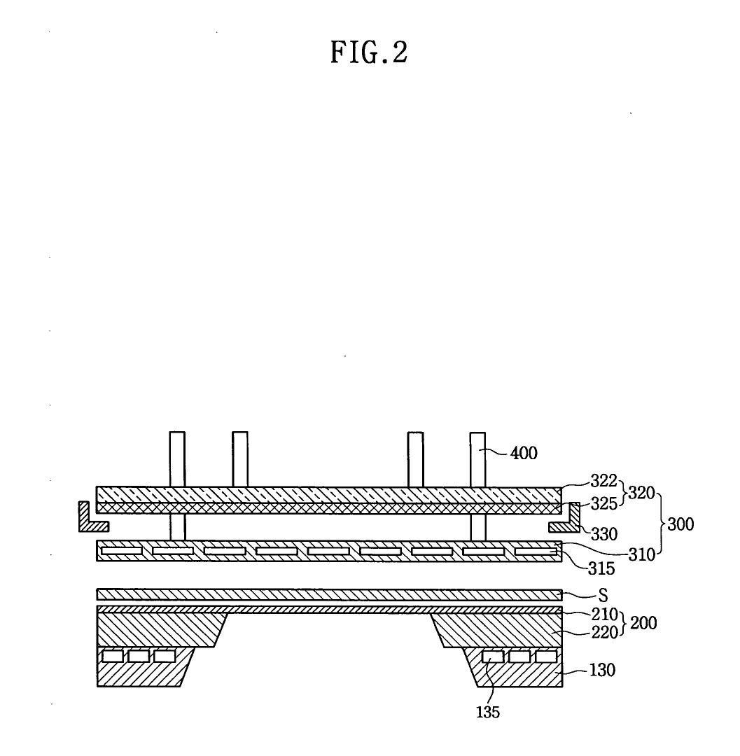

FIG. 1 illustrates a schematic view of a deposition apparatus in accordance with an exemplary embodiment, and FIG. 2 illustrates an enlarged view of a mask assembly and a mask adhesion unit of FIG. 1.

Referring to FIG. 1, the deposition apparatus in accordance with an exemplary embodiment may include a chamber 100, a deposition source 110 disposed in the chamber 100, a mask assembly 200 disposed over the deposition source 110, and a mask adhesion unit 300 disposed over the mask assembly 200. Here, the deposition apparatus in accordance with an exemplary embodiment may further include a mask holder 130 disposed between the mask assembly 200 and a coupling member 120 to readily couple the mask assembly 200 to the chamber 100 and to prevent damage to the mask assembly 200 during the coupling process. The mask holder 130 may be disposed next to a mask frame 220 of the mask assembly 200. The coupling member 120 of the chamber 100 may have a bent shape.

As illustrated in FIGS. 1 and 2, the mask assembly 200 may include the mask frame 220 having an opening and one or a plurality of pattern masks 210 extending to be fixed to the mask frame 220. Each pattern mask 210 may have one or a plurality of slits (not shown) corresponding to the opening of the mask frame 220 so that a deposition material injected or evaporated from the deposition source 110 may be patterned and deposited on a substrate S. In a deposition method using the mask assembly 200, the pattern masks 210 of the mask assembly 200 may be very precisely aligned, and that the mask assembly 200 may be maximally adhered to the substrate S to improve deposition precision of a material deposited on the substrate S through the pattern masks 210 of the mask assembly 200.

The pattern mask 210 may be a fine metal mask (FMM) formed of, e.g., a metal thin film, which may be formed of at least one of steel use stainless (SUS), invar, nickel, cobalt, or an alloy thereof.

The mask frame 220 may be formed of, e.g., a material resistant to deformation from a compression force, i.e., a strong metal material, to minimize deformation when the pattern mask 210 is fixed to the mask frame 220. For example, the mask frame 220 may be formed of the same material as the pattern mask 210 to be readily fixed to the pattern mask 210. Here, to prevent deformation of the mask assembly 200 during the deposition process due to heat in the chamber 100, a coolant passage (not shown) may be formed in the mask frame 220 of the mask assembly 200. The coolant passage may provide a passage in which coolant, e.g., cooling water, etc., may flow to cool the mask assembly 200. The mask frame 220 may have a plurality of coolant passages. When the deposition apparatus in accordance with an exemplary embodiment includes the mask holder 130, a coolant passage 135 may be formed in the mask holder 130 to prevent deformation of the mask assembly 200 without changing strength of the mask frame 220. The coolant passage 135 may provide passage in which cooling water, etc., flows so that the mask assembly 200 may not be deformed due to the heat in the chamber 100. The mask holder 130 may have a plurality of the coolant passages 135.

The mask adhesion unit 300 may be disposed on an opposite side of the mask assembly 200 with respect to the substrate S, so that the substrate S may be interposed between the mask adhesion unit 300 and the mask assembly 200. Here, the mask adhesion unit 300 may be fixed to the chamber 100 by a fixing member 400. The mask adhesion unit 300, i.e., a magnetic assembly 320, may generate a magnetic force and a magnetic field by which the mask assembly 200 adheres to the substrate S, thereby preventing generation of a shadow on the deposition material injected or evaporated from the deposition source 110.

The mask adhesion unit 300 may include a cap plate 310, the magnetic assembly 320 disposed over the cap plate 310, and a magnetic control unit 330 disposed between the edges of the magnetic assembly 320 and the cap plate 310.

The cap plate 310 may prevent damage to the substrate S, e.g., by the magnetic assembly 320, when the mask adhesion unit 300 is in contact with the substrate S, and may have a coolant passage 315, through which coolant, e.g., cooling water, etc., flows, to uniformly maintain the temperature of the substrate S. The coolant passage 315 may be a plurality in number, having a predetermined space between the adjacent coolant passages 315. The cap plate 310 may be between the magnetic assembly 320 and the substrate S, and may overlap e.g., the entire substrate S.

The magnetic assembly 320 may include a magnetic plate 322 and a magnetic material 325 applied to a surface of the magnetic plate 322 facing the cap plate 310. For example, the magnetic material 325 may be a film, e.g., flat, covering the entire surface of the magnetic plate 322 facing the cap plate 310. The magnetic material 325 may be formed of, e.g., a rubber or a metal magnetic material. If the magnetic material 325 is formed of the rubber magnetic material, out-gassing may be generated due to the heat in the chamber 100, thereby decreasing lifespan of an organic emission layer. Therefore, the magnetic material 325 may preferably be formed of the metal magnetic material.

The magnetic control unit 330 may remove or substantially reduce a magnetic force applied to edges of the mask assembly 200 from the magnetic assembly 320. The magnetic control unit 330 may include a magnetic shielding material or a ferrite magnetic material, e.g., steel, and may preferably be a thin film sheet formed of, e.g., steel. For example, as illustrated in FIG. 2, the magnetic control unit 330 may be bent to cover the edge of the magnetic material 325, so the magnetic control unit 330 may overlap, e.g., two surfaces of the magnetic material 325. That is, a first portion of the magnetic control unit 330 may be interposed between the magnetic material 325 and the cap plate 310, and a second portion of the magnetic control unit 330 may be substantially perpendicular to the first portion to overlap a side surface, e.g., entire side surface, of the magnetic material 325. For example, the magnetic control unit 330 may overlap, i.e., cover, an entire edge of the magnetic material 325, e.g., entire perimeter of the magnetic material 325. For example, the magnetic control unit 330 may be on the magnetic material 325.

The deposition process by the deposition apparatus in accordance with an exemplary embodiment will now be described with reference to FIGS. 1 and 2. The deposition source may be disposed on the chamber 100, and the mask assembly 200 may be coupled to the chamber 100 using the mask holder 130.

After placing the substrate S on the mask assembly 200, the magnetic assembly 320 of the mask adhesion unit 300 may be positioned on an opposite side of the mask assembly 200 with respect to the substrate S, which may be interposed therebetween, to apply a magnetic force and a magnetic field so that the mask assembly 200 may be adhered to the substrate S.

Since the mask adhesion unit 300 includes the magnetic control unit 330 disposed at the edge of the magnetic assembly 320 facing the mask assembly 200, a magnetic force and a magnetic field generated from the edge of the magnetic assembly 320 may be removed or substantially reduced by the magnetic control unit 330. As a result, a disproportional application of the magnetic force and magnetic field to the edge of the mask assembly 200 may be eliminated or substantially minimized. In other words, if a magnetic force and magnetic field are stronger at edges of the magnetic material 325 than in a center thereof, the magnetic control unit 330 may minimize magnetic force and magnetic field at edges of the magnetic material 325, so the magnetic force and magnetic field applied to the mask assembly 200 may be substantially uniform, e.g., magnetic force and field applied at edges and center of the mask assembly 200 may be substantially uniform. Therefore, deformation of the slit, i.e., slits in the pattern mask 210 disposed adjacent to edges of the mask assembly, of the mask assembly 200 may be prevented.

When the interior of the chamber 100 is heated to a certain temperature to perform the deposition process, coolant, e.g., cooling water, etc., may be introduced through the coolant passage formed in the mask holder 130, i.e., the coolant passage 135, and/or through the cap plate 310 of the mask adhesion unit 300, i.e., the coolant passage 315, to prevent deformation of the mask assembly 200 and the substrate S due to the heat in the chamber 100.

The deposition material may be injected or may be evaporated from the deposition source 110 to be deposited on the substrate S to form a certain pattern by the slits of the mask assembly 200.

In the mask adhesion unit and the deposition apparatus using the same in accordance with an exemplary embodiment, the magnetic control unit 330 including a magnetic shielding material or a ferrite magnetic material, e.g., steel, may be disposed at the edge of the magnetic material 325 of the mask adhesion unit 300 facing the mask assembly 200 to reduce or shield the magnetic force being applied to the edges of the mask assembly 200 from the magnetic material 325, thereby minimizing disproportional application of magnetic force and magnetic field applied to the edges of the mask assembly 200.

Since a magnetic force and magnetic field of a magnetic material layer is conventionally stronger at an edge thereof than at a center portion thereof, a larger magnetic force and magnetic field may be applied to an edge portion than a center portion of a mask assembly by the magnetic material layer, and thus, a slit disposed adjacent to an edge of the mask assembly may be deformed. As can be seen from the foregoing, a mask adhesion unit and a deposition apparatus using the same in accordance with an exemplary embodiment may control a magnetic force and magnetic field being applied to an edge of the mask assembly via a magnetic control unit to minimize disproportional application of magnetic force and magnetic field to an edge of the mask assembly, thereby preventing deformation of a slit of the mask assembly.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A mask adhesion unit for a deposition apparatus, comprising:
a magnetic assembly;
a cap plate spaced apart from the magnetic assembly; and
a magnetic control unit between edges of the magnetic assembly and the cap plate.

2. The mask adhesion unit as claimed in claim 1, wherein the magnetic control unit includes a magnetic shielding material or a ferrite magnetic material.

3. The mask adhesion unit as claimed in claim 2, wherein the magnetic control unit includes a ferrite magnetic material, the magnetic control unit being a thin film sheet formed of steel.

4. The mask adhesion unit as claimed in claim 1, wherein the magnetic control unit overlaps two surfaces of the magnetic assembly.

5. The mask adhesion unit as claimed in claim 1, wherein a portion of the magnetic control unit is between the magnetic assembly and the cap plate.

6. The mask adhesion unit as claimed in claim 1, wherein the cap plate has a plurality of coolant passages.

7. The mask adhesion unit as claimed in claim 1, wherein the magnetic assembly includes a magnetic plate and a magnetic material applied to a surface of the magnetic plate facing the cap plate.

8. The mask adhesion unit as claimed in claim 7, wherein the magnetic control unit overlaps two surfaces of the magnetic material, the magnetic control unit covering a side surface of the magnetic material.

9. The mask adhesion unit as claimed in claim 7, wherein the magnetic material of the magnetic assembly is a metal-based material.

10. A deposition apparatus, comprising:
a chamber;
a deposition source in the chamber;
a mask assembly over the deposition source; and
a mask adhesion unit over the mask assembly,
wherein the mask adhesion unit includes a magnetic assembly, a cap plate spaced apart from the magnetic assembly, and a magnetic control unit between edges of the magnetic assembly and the cap plate.

11. The deposition apparatus as claimed in claim 10, wherein the magnetic control unit includes a magnetic shielding material or a ferrite magnetic material.

12. The deposition apparatus as claimed in claim 11, wherein the magnetic control unit includes a ferrite magnetic material, the magnetic control unit being a thin film sheet formed of steel.

13. The deposition apparatus as claimed in claim 10, wherein the cap plate has a plurality of coolant passages.

14. The deposition apparatus as claimed in claim 10, wherein the magnetic assembly includes a magnetic plate and a magnetic material applied to a surface of the magnetic plate facing the cap plate.

15. The deposition apparatus as claimed in claim 14, wherein the magnetic material of the magnetic assembly is a metal-based material.

16. The deposition apparatus as claimed in claim 10, wherein the mask assembly includes a mask frame having an opening and at least one pattern mask extending to be fixed to the mask frame.

17. The deposition apparatus as claimed in claim 16, wherein the pattern mask is a fine metal mask.

18. The deposition apparatus as claimed in claim 16, wherein the mask frame is formed of a metal material.

19. The deposition apparatus as claimed in claim 10, further comprising a mask holder for coupling the mask assembly to the chamber.

20. The deposition apparatus as claimed in claim 19, wherein the mask holder has a plurality of coolant passages.
